(19) United States
(12) Patent Application Publication
(10) Pub. No.: US 2026/0036651 A1
(43) Pub. Date: Feb. 5, 2026

(54) ERROR CALIBRATION METHOD OF NV VECTOR MAGNETOMETER, DEVICE, MEDIUM AND PRODUCT

(71) Applicant: North University of China, Taiyuan City (CN)

(72) Inventors: Zongmin Ma, Taiyuan City (CN); Jun Liu, Taiyuan City (CN); Jun Tang, Taiyuan City (CN); Xiaoming Zhang, Taiyuan City (CN); Chenchen Tang, Taiyuan City (CN); Doudou Zheng, Taiyuan City (CN); Huanfei Wen, Taiyuan City (CN); Zhonghao Li, Taiyuan City (CN); Hao Guo, Taiyuan City (CN); Yingjie Yang, Taiyuan City (CN); Jianghao Fu, Taiyuan City (CN)

(21) Appl. No.: 18/983,533

(22) Filed: Dec. 17, 2024

(30) Foreign Application Priority Data
Jul. 31, 2024 (CN) 202411044995.1

(51) Int. Cl. G01R 33/00; G01R 33/032

(52) U.S. Cl. CPC G01R 33/0029; G01R 33/0035; G01R 33/032

(57) ABSTRACT

An error calibration method of a nitrogen-vacancy center (NV) vector magnetometer is disclosed. The method includes acquiring corresponding magnetic field intensity NV vector magnetometer measured data in various postures and constructing an error expression of the NV vector magnetometer. The error expression of the NV vector magnetometer is a relational expression among the magnetic field intensity measured data, magnetic field intensity real data and an error coefficient and the error coefficient includes a combination coefficient and a zero-bias error coefficient. All the magnetic field intensity measured data are fit based on an ellipsoid fitting method. The error coefficient is solved to obtain a determined error coefficient. The determined error coefficient is substituted into the error expression of the NV vector magnetometer to obtain an error model of the NV vector magnetometer. The magnetic field intensity measured data is substituted into the error model of the NV vector magnetometer.

### CROSS-REFERENCE TO RELATED APPLICATIONS

This patent application claims the benefit and priority of Chinese Patent Application No. 2024110449951, filed with the China National Intellectual Property Administration on Jul. 31, 2024, the disclosure of which is incorporated by reference herein in its entirety as part of the application.

### TECHNICAL FIELD

The present disclosure relates to the technical field of magnetic sensing and, in particular embodiments, to error calibration method of a nitrogen-vacancy center (NV) vector magnetometer, a device, a medium and a product.

### BACKGROUND

Compared with other types of magnetometers, a diamond nitrogen-vacancy center (NV) magnetometer is high in sensitivity, easy to be integrated and strong in working adaptability, which can meet the requirements of high precision in practical applications and has been widely used in the fields of magnetic abnormal data detection, aerospace and geomagnetic navigation. The appearance of the NV magnetic vector sensing technology makes micro-scale ultra-high-precision magnetic vector sensing possible, which injects new vitality into magnetic database acquisition and real-time magnetic data measurement. Moreover, the NV magnetometer has broad development and application prospects in various fields because of its advantages such as natural vector characteristics, high sensitivity, high resolution and high stability.

However, there are errors in the manufacturing process of the NV magnetometer itself, mainly including a non-orthogonal error, a scale factor error and a zero-bias error, which interfere with NV magnetometer and affect the measurement accuracy. Therefore, these errors must be calibrated before NV magnetometer is used.

An ellipsoid fitting method based on a least square method is a common correction method. The basic idea is that the three-dimensional magnetic trajectory of the magnetic field vector is a distorted ellipsoid deviating from the origin, and the shape and the position of the ellipsoid are determined by the error coefficient. The three-dimensional magnetic trajectory of the magnetic field vector is corrected into a sphere with a radius equal to the magnetic field modulus value by correction, thereby achieving the purpose of calibrating the original magnetic field data.

It can be seen that the existing research on the diamond nitrogen-vacancy center (NV) magnetometer only involves the measurement of the NV center vector magnetic field. The evaluation of the non-orthogonal error, the scale factor error and the zero-bias error, and the principle of about the compensating manner are not clear. Therefore, it is necessary to study and compensate for its error, so as to achieve the purpose that the magnetic field measured data is more consistent with the magnetic field real data, and then play a role in the fields of magnetic abnormal data detection, aerospace and unmanned aerial vehicles.

### SUMMARY

Embodiments of the present disclosure provide an error calibration method of a nitrogen-vacancy center (NV) vector magnetometer, a device, a medium and a product, which can realize the evaluation and calibration of the non-orthogonal error, the scale factor error and the zero-bias error and improve the precision of the NV vector magnetometer in measuring magnetic field intensity.

In a first aspect, the present disclosure provides an error calibration method of a nitrogen-vacancy center (NV) vector magnetometer. The method includes acquiring corresponding magnetic field intensity NV vector magnetometer measured data in various postures and constructing an error expression of the NV vector magnetometer. The error expression of the NV vector magnetometer is a relational expression among the magnetic field intensity measured data, magnetic field intensity real data and an error coefficient. The error coefficient includes a combination coefficient and a zero-bias error coefficient, and the combination coefficient includes a non-orthogonal error coefficient and a scale factor error coefficient. All the magnetic field intensity measured data are fit based on an ellipsoid fitting method of a least square method and the error coefficient is solved to obtain the determined error coefficient. The determined error coefficient is substituted into the error expression of the NV vector magnetometer to obtain an error model of the NV vector magnetometer. The magnetic field intensity measured data is substituted into the error model of the NV vector magnetometer to obtain the corresponding magnetic field intensity real data.

In a second aspect, the present disclosure provides a computer device that includes a memory, a processor and a computer program which is stored in the memory and is executable on the processor. The processor executes the computer program to implement the steps of the error calibration method of the NV vector magnetometer described above.

In a third aspect, the present disclosure provides a computer-readable storage medium on which a computer program is stored. The computer program, when executed by a processor, implements the steps of the error calibration method of the NV vector magnetometer described above.

In a fourth aspect, the present disclosure provides a computer program product, including a computer program. The computer program, when executed by a processor, implements the steps of the error calibration method of the NV vector magnetometer described above.

According to a specific embodiment provided by the present disclosure, the present disclosure can provide the following technical effects.

The present disclosure provides an error calibration method of a nitrogen-vacancy center (NV) vector magnetometer, a device, a medium and a product. The method includes acquiring corresponding magnetic field intensity NV vector magnetometer measured data in various postures; constructing an error expression of the NV vector magnetometer, wherein the error expression of the NV vector magnetometer is a relational expression among the magnetic field intensity measured data, magnetic field intensity real data and an error coefficient, the error coefficient includes a combination coefficient and a zero-bias error coefficient, and the combination coefficient includes a non-orthogonal error coefficient and a scale factor error coefficient; fitting all the magnetic field intensity measured data based on an ellipsoid fitting method of a least square method, and solving the error coefficient to obtain the determined error coefficient; substituting the determined error coefficient into the error expression of the NV vector magnetometer to obtain an error model of the NV vector magnetometer; substituting the magnetic field intensity measured data into the error model of the NV vector magnetometer to obtain the corresponding magnetic field intensity real data. The method realizes the evaluation and calibration of a non-orthogonal error, a scale factor error and a zero-bias error, and then realizes the high-precision magnetic field intensity measurement of the NV vector magnetometer.

### BRIEF DESCRIPTION OF THE DRAWINGS

In order to explain the embodiments of the present disclosure or the technical schemes in the prior art more clearly, the drawings that need to be used in the embodiments will be briefly introduced hereinafter. The drawings in the following description are only some embodiments of the present disclosure. For those skilled in the art, other drawings can be obtained according to these drawings without creative labor.

FIG. 1 is an application environment diagram of an error calibration method of an NV vector magnetometer according to a first embodiment of the present disclosure.

FIG. 2 is a schematic flowchart of an error calibration method of an NV vector magnetometer according to the first embodiment of the present disclosure.

FIG. 3 is a schematic diagram of establishing a diamond coordinate system of an NV vector magnetometer according to the first embodiment of the present disclosure.

FIG. 4 is a schematic diagram of establishing a probe coordinate system of an NV vector magnetometer according to the first embodiment of the present disclosure.

FIG. 5 is a schematic diagram of acquiring magnetic field data of an NV vector magnetometer in different postures according to the first embodiment of the present disclosure.

FIG. 6 is a schematic diagram of three included angles of non-orthogonal error coefficients according to the first embodiment of the present disclosure.

FIG. 7 is a schematic structural diagram of a computer device according to a second embodiment of the present disclosure.

### DETAILED DESCRIPTION OF ILLUSTRATIVE EMBODIMENTS

The technical schemes in the embodiments of the present disclosure will be clearly and completely described with reference to the drawings in the embodiments of the present disclosure hereinafter. Obviously, the described embodiments are only some embodiments of the present disclosure, rather than all of the embodiments. Based on the embodiment of the present disclosure, all other embodiments obtained by those skilled in the art without creative labor fall within the scope of protection of the present disclosure.

In order to make the above objects, features and advantages of the present disclosure more obvious and understandable, the present disclosure will be explained in further detail with reference to the drawings and detailed description hereinafter.

A first embodiment will now be described.

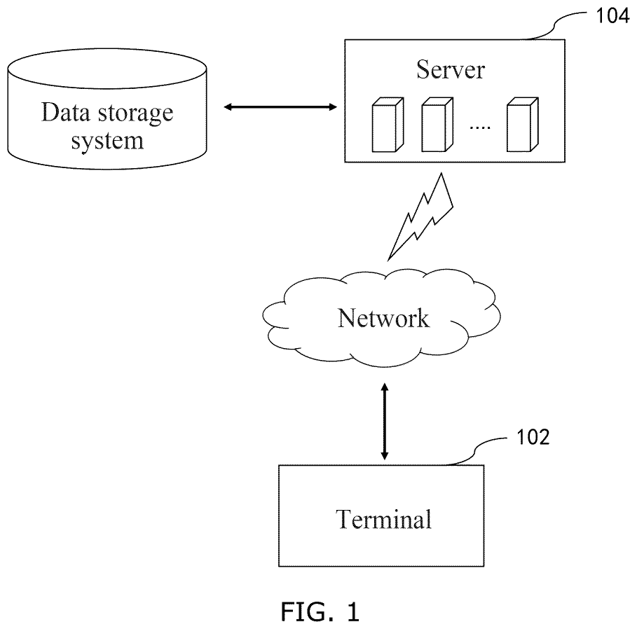

The error calibration method of the NV vector magnetometer according to an embodiment of the present disclosure can be applied to the application environment as shown in FIG. 1. The terminal 102 is communicated with the server 104 through a network. The data storage system can store data that the server 104 needs to process. The data storage system can be provided separately, integrated on the server 104, or placed on the cloud or other servers. The terminal 102 can send the magnetic field intensity measured data measured by the NV vector magnetometer in various postures to the server 104.

After the server 104 receives the magnetic field intensity measured data, the server 104 first constructs the relationship among the magnetic field intensity measured data, the magnetic field intensity real data and the error coefficient, that is, the error expression of the NV vector magnetometer; thereafter, fits all the magnetic field intensity measured data based on an ellipsoid fitting method of a least square method, and solves the error coefficient to obtain the determined error coefficient; subsequently, determines an error model of the NV vector magnetometer based on the determined error coefficient and the error expression of the NV vector magnetometer; and finally substitutes the magnetic field intensity measured data into the error model of the NV vector magnetometer to obtain the corresponding magnetic field intensity real data. The server 104 can feed back the obtained magnetic field intensity real data to the terminal 102. In addition, in some embodiments, the error calibration method of the NV vector magnetometer can also be realized by the server 104 or the terminal 102 alone. For example, the terminal 102 can directly correct the errors of the magnetic field intensity measured data, or the server 104 can correct the errors of the magnetic field intensity measured data after acquiring the magnetic field intensity measured data from the data storage system.

The terminal 102 can be, but not limited to, various desktop computers, notebook computers, smart phones, tablet computers, Internet of Things devices and portable wearable devices. The Internet of Things devices can be smart speakers, smart TVs, smart air conditioners, smart vehicle-mounted devices. etc. The portable wearable devices can be smart watches, smart bracelets, headsets, etc. The server 104 can be realized by an independent server or a server cluster consisted of a plurality of servers, and can also be a cloud server.

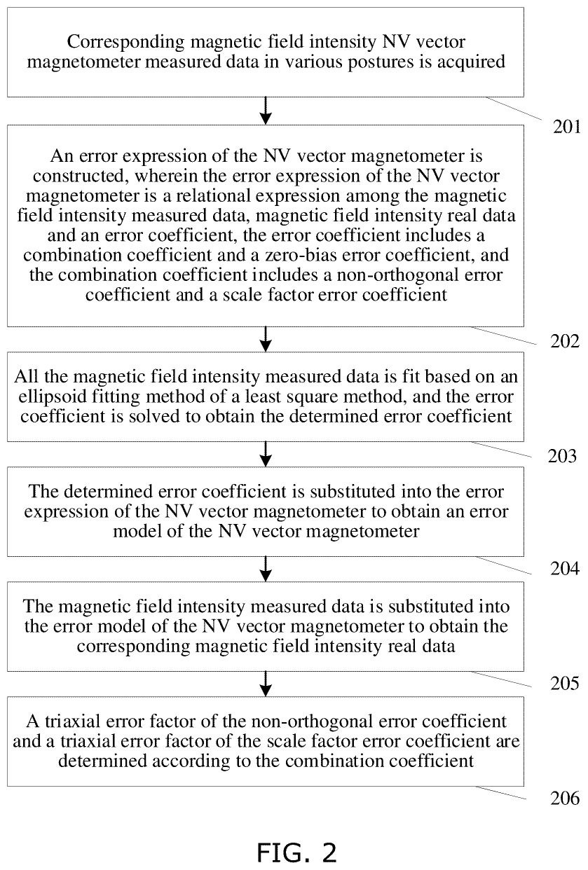

In an exemplary embodiment, before practical application, the NV vector magnetometer is calibrated by using the error calibration method of the NV vector magnetometer shown in FIG. 2, so as to determine the relationship matrix between the real magnetic field and the measured magnetic field. The method is executed by a computer device. Specifically, the method can be executed by a computer device such as a terminal or a server alone, or can be executed jointly by the terminal and the server. In the embodiment of the present disclosure, taking the application of the method to the server 104 in FIG. 1 as an example, the method is explained, including the following Step 201 to Step 208.

Step 201: Corresponding magnetic field intensity NV vector magnetometer measured data in various postures is acquired. The magnetic field data in different postures is acquired in such a manner that the probe of the NV vector magnetometer is placed in a shielding cylinder, the coil in the shielding cylinder is controlled to generate a full-space rotating magnetic field with a constant total field intensity by using a program-controlled current source, and then the relationship model of an NV four-axis coordinate system, a diamond coordinate system and a sensor coordinate system is established to obtain the resonance frequency and the vector magnetic field conversion coefficient matrix, so as to measure the three-axis vector magnetic field.

The NV center in a diamond has four different crystallographic axes, which can be used for full vector magnetic field measurement. When the external magnetic field acts on an ensemble diamond, the magnetic field will be projected on the NV axis, the change of the magnetic field induced by the NV axis will shift four pairs of resonance frequencies, and the magnitude of the shift is only related to the magnitude of the magnetic field acting on the NV axis. In this way, the magnetic field vector measurement can be realized only by inverting the shift of the four pairs of resonance frequencies.

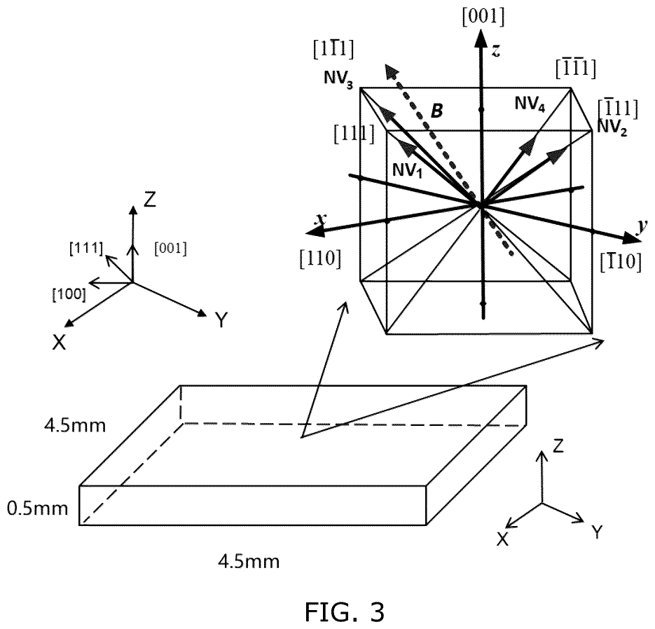

On this basis, the corresponding relationships among the NV center four-axis coordinate system, the diamond coordinate system and the probe coordinate system of the NV vector magnetometer are established to measure the magnetic field vector. The establishment of the diamond coordinate system is related to the cell structure. At present, diamonds commonly used in the laboratory are made by a high-temperature and high-pressure method and cut along the [100] direction. The establishment of the NV center four-axis coordinate system to the diamond coordinate system is shown in FIG. 3, in which, taking a single cell in the ensemble diamond as an example, the [110] direction is x axis, the [1̅10] direction is y axis, and the [001] direction is z axis. The whole ensemble diamond is established with the midpoint of the square surface of the ensemble diamond as the origin, the connecting line between the midpoint and the angle in the [110] direction as the x axis, the connecting line between the midpoint and the angle in the [1̅10] direction as the y axis, and the height of the cuboid as the z axis.

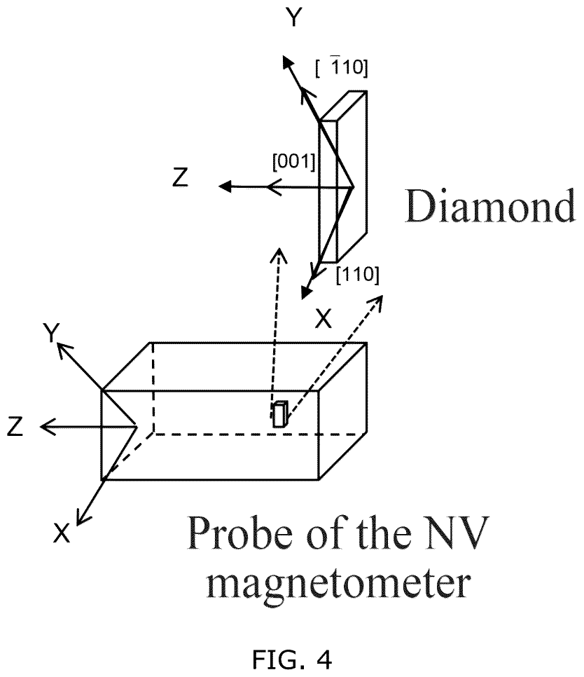

Based on the diamond coordinate system and its position in the probe, the probe coordinate system of the NV vector magnetometer is constructed, as shown in FIG. 4. In the actual calibration process, the probe of the NV vector magnetometer is placed in the three-axis Helmholtz coil, so that the x or y direction is consistent with the induced magnetic field of the coil, and only the zero points of two demodulation curves will shift and have the same amplitude. When the z direction of the probe of the NV vector magnetometer is consistent with the coil direction, the zero points of the four NV axis demodulation curves will be shifted, and their shifts are the same. In this way, the direction of the probe of the NV vector magnetometer can be judged.

The measurement of the vector magnetic field of the NV vector magnetometer needs to use four NV axes to determine the relationship between the four-axis resonance frequency shift and the three-axis magnetic field, and the relationship can be expressed as:

$$[ \begin{matrix}Δ {f}_{1} \\ Δ {f}_{2} \\ Δ {f}_{3} \\ Δ {f}_{4}\end{matrix} ] = A [ \begin{matrix}{B}_{x} \\ {B}_{y} \\ {B}_{z}\end{matrix} ]$$

where Δfᵢ is the shift of the resonant frequency (i=1,2,3,4), Bₓ, B_{y}, B_{z} are the three-axis magnetic field components detected by the sensor, and A is the relationship matrix between the four-axis resonant frequency shift and the three-axis magnetic field.

The matrix A is defined as:

$$A = [ \begin{matrix}\frac{\partial {v}_{λ}}{\partial {B}_{x}} & \frac{\partial {v}_{λ}}{\partial {B}_{y}} & \frac{\partial {v}_{λ}}{\partial {B}_{z}} \\ \frac{\partial {v}_{χ}}{\partial {B}_{x}} & \frac{\partial {v}_{χ}}{\partial {B}_{y}} & \frac{\partial {v}_{χ}}{\partial {B}_{z}} \\ \frac{\partial {v}_{ϕ}}{\partial {B}_{x}} & \frac{\partial {v}_{ϕ}}{\partial {B}_{y}} & \frac{\partial {v}_{ϕ}}{\partial {B}_{z}} \\ \frac{\partial {v}_{κ}}{\partial {B}_{x}} & \frac{\partial {v}_{κ}}{\partial {B}_{y}} & \frac{\partial {v}_{κ}}{\partial {B}_{z}}\end{matrix} ]$$

where v_{λ}, vₓ, v_{φ} and vₖ correspond to the frequency shift of four NV axes, respectively. The matrix A is mainly related to the applied bias magnetic field \vec{B}₀, the strain parameter \vec{M}_{z} and the temperature-related zero-field splitting D. When any component of the bias magnetic field \vec{B}₀ changes by 10 μT, it will have a slight influence on A, but this influence is very small and almost negligible. In some cases, this influence is even less than 0.01%. The influence of the strain parameter \vec{M}_{z} on A is also very limited, and its doubling influence on A is far less than 1%. In addition, the influence of the fluctuation of the zero-field splitting D on A is also less than 0.01%. Therefore, the influence of these factors can be ignored in the actual process.

In the case of a weak magnetic field intensity and a low strain, the matrix A is determined by the unit vector of the NV symmetry axis, the expression of A_{L.Z} (the ideal case of the matrix A) is:

$${A}_{L . Z} = \frac{{g}_{\text{?}} {μ}_{B}}{h} [ \begin{matrix}0 & - \sqrt{2 / 3} & - \sqrt{1 / 3} \\ \sqrt{2 / 3} & 0 & - \sqrt{1 / 3} \\ 0 & - \sqrt{2 / 3} & \sqrt{1 / 3} \\ \sqrt{2 / 3} & 0 & \sqrt{1 / 3}\end{matrix} ]$$

$$\text{?} \text{indicates text missing or illegible when filed}$$

Because the bias magnetic field \vec{B}₀ has a magnetic field component on each NV axis, the requirements of the magnetic field projection on the NV axis for ODMR frequency shift measurement cannot be met. Therefore, A_{L.Z} and A are different, so that it is necessary to determine A by using an experimental method.

For each magnetometer, the value of A is different. This is determined in the range of 0.1 A to 1 A (78.2 μT/A) by combining a triaxial fluxgate magnetometer and a triaxial Helmholtz coil. When the coils are aligned along the x axis of a fluxgate magnetometer probe, the current increases in steps of 0.1 A, and the peak value of the magnetic field changes to obtain the relationship between the magnetic field and the current. On this basis, the NV vector magnetometer is placed at the same position, a stepped magnetic field of 0.1 A is applied to the x axis by using the three-axis Helmholtz coil, and the corresponding relationship between the NV four-axis frequency shift and the magnetic field is obtained. The y axis and the z axis are executed in the same way, the corresponding relationship between the NV four-axis frequency shift and the magnetic field is obtained by linear fitting in each axis direction, and then the A matrix is determined.

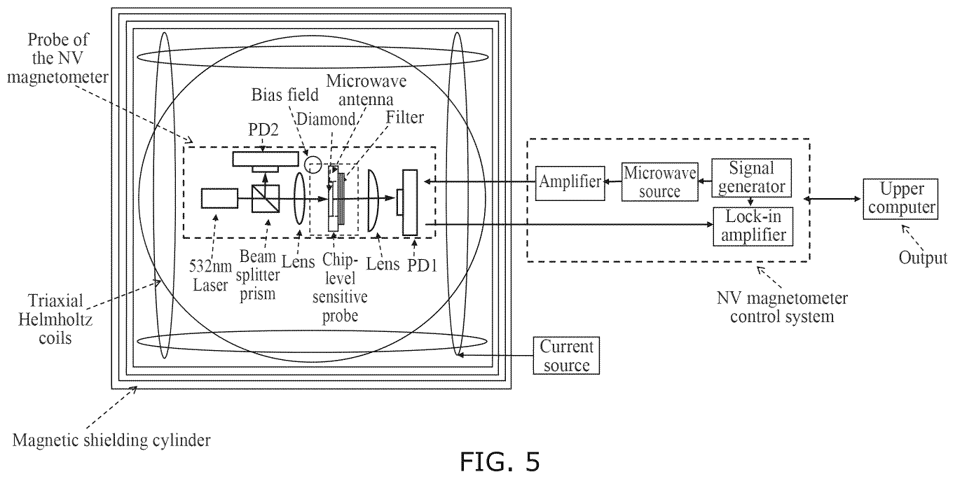

The schematic diagram of acquiring the NV vector magnetometer measured data in different postures is shown in FIG. 5. The probe of the NV vector magnetometer is placed in a shielding cylinder, and the coil in the shielding cylinder is controlled to generate a full-space rotating magnetic field with a constant total field intensity by using a program-controlled current source. The period is set as T. The probe of the NV vector magnetometer is randomly rotated so that the data measured by its posture in a period covers the set space range as much as possible, and the magnetic field intensity data under the condition of magnetic field rotation in this period is recorded and saved. In order to make the calibration method feasible, there should be no less than six postures. The set space range is the three-dimensional space range where the ellipsoid to be fitted is located.

In the actual use process, as shown in FIG. 5, the diamond excitation and the fluorescence signals are collected by the probe of the NV vector magnetometer to realize the perception of magnetic signals, and the magnetic signals are sent to the control system. The control system acquires the magnetic signals, modulates and demodulates the magnetic signals, calculates the vector magnetic field information, and sends the calculated results to the upper computer. The upper computer obtains high-precision magnetic field information according to the pre-calibrated matrix.

Step 202: An error expression of the NV vector magnetometer is constructed, wherein the error expression of the NV vector magnetometer is a relational expression among the magnetic field intensity measured data, magnetic field intensity real data and an error coefficient, the error coefficient includes a combination coefficient and a zero-bias error coefficient, and the combination coefficient includes a non-orthogonal error coefficient and a scale factor error coefficient.

As shown in FIG. 4, the vector magnetic field measurement of the NV vector magnetometer generally needs to establish three-axis coordinate systems that are orthogonal in pairs, and project the magnetic fields of four axes of the NV onto three axes of x, y and z. However, due to the limitation of the diamond cutting process and the NV center manufacturing process, there are errors in the calculation of the three-axis magnetic field, which leads to inaccurate measured data. Therefore, the errors of the diamond nitrogen-vacancy center (NV) magnetometer can be mainly classified into non-orthogonal errors, scale factor errors and zero-bias errors.

When the NV vector magnetometer is calculated, the established ideal three-axis coordinate systems are orthogonal in pairs. However, due to the limitation of the diamond cutting process and the uncertainty of manual installation in the probe machining process, the actual laboratory coordinate system established according to diamond is not completely coincident with the ideal coordinate systems that are orthogonal in pairs in the vector calculation process, resulting in non-orthogonal errors. Therefore, the non-orthogonal error matrix of the NV vector magnetometer can be expressed as:

$${K}_{non} = [ \begin{matrix}cos α & 0 & sin α \\ sin β cos γ & cos β cos γ & sin γ \\ 0 & 0 & 1\end{matrix} ] \qquad ( 1 )$$

The scale factor error is the limitation of the NV center manufacturing process, which leads to the uneven centers of four axes of the NV, thus making the NV vector magnetometer result in errors due to different sensitivities to the magnetic field vector projected on each axis. Its mathematical model can be expressed as:

$$\text{?} = [ \begin{matrix}{k}_{x} & 0 & 0 \\ 0 & {k}_{y} & 0 \\ 0 & 0 & {k}_{z}\end{matrix} ] \qquad ( 2 )$$

$$\text{?} \text{indicates text missing or illegible when filed}$$

Different from other absolute magnetometers, the NV vector magnetometer can measure the change of the magnetic field, which is a relative magnetometer. In the process of calculating the magnetic field vector, when the voltage signal measured by the magnetometer is converted into the magnetic field signal, there will be an uncertain voltage shift, which can be defined as the zero-bias error after converting the magnetic field data. The zero-bias error matrix of the NV vector magnetometer can be expressed as:

$${B}_{0} = {[ {B}_{0 , x} , {B}_{0 , y} , {B}_{0 , z} ]}^{T} \qquad ( 3 )$$

Therefore, the error expression of the NV vector magnetometer is:

$${B}_{c} = {( {K}_{non} {K}_{sca} )}^{- 1} ▯ ( {B}_{s} - {B}_{0} ) = {K}^{- 1} ▯ ( {B}_{s} - {B}_{0} ) \qquad ( 4 )$$

where B_{c} is the magnetic field intensity measured data; Kₙₒₙ is the non-orthogonal error coefficient; K_{sca} is the scale factor error coefficient; Bₛ is the corresponding magnetic field intensity real data; B₀ is the zero-bias error coefficient; K is the combination coefficient. K is a matrix array with 3 rows and 3 columns. The matrix array includes the triaxial error factor of the non-orthogonal error coefficient and the triaxial error factor of the scale factor error coefficient.

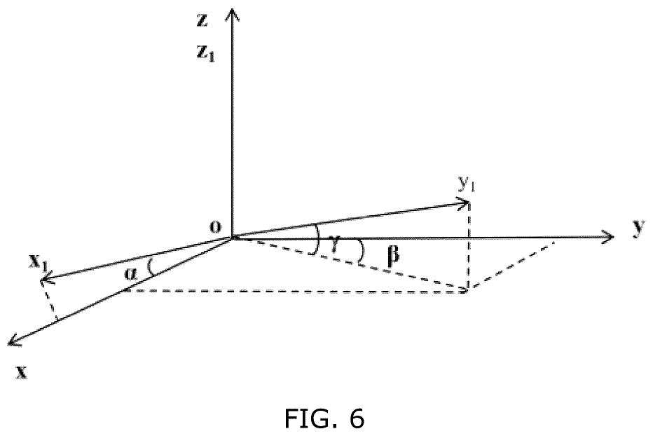

Equation (4) can be detailed as follows:

$$[ \begin{matrix}{B}_{c , x} \\ {B}_{c , y} \\ {B}_{c , z}\end{matrix} ] = [ \begin{matrix}1 / \text{?} & 0 & - α / \text{?} \\ - β / {k}_{x} & 1 / {k}_{y} & - γ / \text{?} \\ 0 & 0 & 1 / \text{?}\end{matrix} ] ( [ \begin{matrix}\text{?} \\ \text{?} \\ \text{?}\end{matrix} ] - [ \begin{matrix}{B}_{0 , x} \\ {B}_{0 , y} \\ {B}_{0 , z}\end{matrix} ] ) \qquad ( 5 )$$

$$\text{?} \text{indicates text missing or illegible when filed}$$

where B_{c,x}, B_{c,y} and B_{c,z} are the measured values of the x-axis magnetic field intensity, of the y-axis magnetic field intensity and of the z-axis magnetic field intensity, respectively; kₓ, k_{y} and k_{z} are an x-axis error factor, a y-axis error factor and a z-axis error factor of the scale factor error coefficient, respectively; α, β and γ are three included angles of the non-orthogonal error coefficient, respectively. As shown in FIG. 6, it is assumed that the ideal triaxial measuring axes of the sensor are x, y and z, and the actual triaxial measuring axes are x₁, y₁ and z₁. Assuming that the z and z₁ axes are coincided with each other, x₁ is located in the xoz plane, and the included angle between x₁ and the x axis is α. The included angle between the projection of the y₁ axis in the xoy plane and the y axis is β, and the included angle between the y₁ axis and the xoy plane is γ. B_{s,x}, B_{s,y} and B_{s,z} are the true values of the x-axis magnetic field intensity, the y-axis magnetic field intensity and the z-axis magnetic field intensity, respectively; B_{o,x}, B_{o,y} and B_{o,z} are the x-axis error factor, y-axis error factor and z-axis error factor of the zero-bias error coefficient, respectively.

It should be noted that the expressions of the error model of the NV vector magnetometer are also Equations (4) and (5), and the only difference from the error expressions of the NV vector magnetometer is that the error model of the NV vector magnetometer is a known error coefficient (that is, the error coefficient obtained by solving through the following steps).

Step 203: All the magnetic field intensity measured data is fit based on an ellipsoid fitting method of a least square method, and the error coefficient is solved to obtain the determined error coefficient.

Step 203 includes the following steps.

Step 203-1: An objective function is established based on an ellipsoid parameter and a first distance, taking the minimum sum of squares of all the first distances as the objective, wherein the first distance is the distance from a magnetic field intensity measured data point to an ellipsoid surface, and the magnetic field intensity measured data point is a three-dimensional coordinate point of the magnetic field intensity measured data.

The influence from the errors of the NV vector magnetometer will distort the original spherical surface of the three-dimensional magnetic trajectory into an ellipsoid surface, and the quadratic equation of the ellipsoid surface is:

$$\begin{matrix}F ( ξ , v ) = {a}_{x}^{2} + {b}_{y}^{2} + {c}_{z}^{2} + 2 dxy + 2 exz + 2 fyz + 2 px + 2 qy + 2 rz + g \\ = 0\end{matrix} \qquad ( 6 )$$

where x, y, and z are points on the ellipsoid, that is, three-dimensional coordinate points of the magnetic field intensity measured data, a, b, c, d, e, f, p, q, r and g are 10 parameters related to the ellipsoid, and a, b, c, d, e, f, p, q, r and g form the ellipsoid parameter ξ, and ξ is a one-dimensional array.

Ellipsoid fitting is to seek a set of ellipsoid parameters ξ to minimize the sum of the squares of the distance from the three-dimensional coordinate points of all magnetic field intensity measured data to the ellipsoid surface. The expression of the objective function is:

$$m \text{?} n {‖ F ( ξ , {V}_{i} ) ‖}^{2} = m \text{?} n \text{?} \qquad ( 7 )$$

$$D = [ \begin{matrix}{x}_{1}^{2} & {y}_{1}^{2} & {z}_{1}^{2} & 2 {x}_{1} {y}_{1} & 2 {x}_{1} {z}_{1} & 2 {y}_{1} {z}_{1} & 2 {x}_{1} & 2 {y}_{1} & 2 {z}_{1} & 1 \\ {x}_{2}^{2} & {y}_{2}^{2} & {z}_{2}^{2} & 2 {x}_{2} {y}_{2} & 2 {x}_{2} {z}_{2} & 2 {y}_{1} {z}_{2} & 2 {x}_{2} & 2 {y}_{2} & 2 {z}_{2} & 1 \\ ⋮ & ⋮ & ⋮ & ⋮ & ⋮ & ⋮ & ⋮ & ⋮ & ⋮ & ⋮ \\ ⋮ & ⋮ & ⋮ & ⋮ & ⋮ & ⋮ & ⋮ & ⋮ & ⋮ & ⋮ \\ {x}_{N}^{2} & {y}_{N}^{2} & {z}_{N}^{2} & 2 {x}_{N} {y}_{N} & 2 {x}_{N} {z}_{N} & 2 {y}_{N} {z}_{N} & 2 {x}_{N} & 2 {y}_{N} & 2 {z}_{N} & 1\end{matrix} ]$$

$$where$$

$$V = [ \begin{matrix}{x}^{2} & {y}^{2} & {z}^{2} & 2 xy & 2 xz & 2 yz & 2 x & 2 y & 2 z & {1 ]}^{- T} ,\end{matrix}$$

$$\text{?} \text{indicates text missing or illegible when filed}$$

Vᵢ is an i-th set of data of V, that is,

$${V}_{i} = {[ \begin{matrix}{x}_{1}^{2} & {y}_{1}^{2} & {z}_{1}^{2} & 2 {x}_{1} {y}_{1} & 2 {x}_{1} {z}_{1} & 2 {y}_{1} {z}_{1} & 2 {x}_{1} & 2 {y}_{1} & 2 {z}_{1} & 1 \\ {x}_{2}^{2} & {y}_{2}^{2} & {z}_{2}^{2} & 2 {x}_{2} {y}_{2} & 2 {x}_{2} {z}_{2} & 2 {y}_{1} {z}_{2} & 2 {x}_{2} & 2 {y}_{2} & 2 {z}_{2} & 1 \\ ⋮ & ⋮ & ⋮ & ⋮ & ⋮ & ⋮ & ⋮ & ⋮ & ⋮ & ⋮ \\ ⋮ & ⋮ & ⋮ & ⋮ & ⋮ & ⋮ & ⋮ & ⋮ & ⋮ & ⋮ \\ {x}_{i}^{2} & {y}_{i}^{2} & {z}_{i}^{2} & 2 {x}_{i} {y}_{i} & 2 {x}_{i} {z}_{i} & 2 {y}_{i} {z}_{i} & 2 {x}_{i} & 2 {y}_{i} & 2 {z}_{i} & 1\end{matrix} ]}^{- T}$$

Step 203-2: The objective function is solved by using a least square method to determine the ellipsoid parameter.

The ellipsoid parameter is determined by using the least square method. When the constraint condition of kJ−I²=1 is satisfied, the fitted spherical surface can be determined as an ellipsoid surface, and the distance from the measured data to the ellipsoid surface is the minimal. The matrix form of the constraint condition is determined by the C matrix consisted of k, and the optimal k value is determined by the dichotomy, where I=a+b+c; J=ab+bc+ac−d²−e²−f².

According to Lagrange theorem, the form of the objective function becomes:

$${D}^{T} D ξ = λ C ξ \qquad ( 8 )$$

$${ξ}^{T} C ξ = 1$$

In order to solve Equation (8), the matrix D, the scattering matrix S(S=D^{T}D) and the parameter vector are decomposed,

$${ξ}_{2} = - {S}_{22}^{- 1} {S}_{12}^{T} {ξ}_{1}$$

can be solved. The eigenvalues and the eigenvectors of the matrix

$${C}_{1}^{- 1} ( {S}_{11} - {S}_{12} {S}_{22}^{- 1} {S}_{12}^{T} )$$

are solved. One and only one of the eigenvalues is greater than 0, and the corresponding eigenvector ξ can be obtained from the eigenvalue.

$$ξ = {[ \begin{matrix}a & b & c & d & e & f & p & q & r & g\end{matrix} ]}^{T} = [ {ξ}_{1} / {ξ}_{2} ] ;$$

$$where$$

$${ξ}_{1} = {[ \begin{matrix}a & b & c & d & e & f\end{matrix} ]}^{T} , {ξ}_{1} = {[ \begin{matrix}p & q & r & g\end{matrix} ]}^{T} ;$$

The matrix D is decomposed, where D=[D₁D₂];

$${D}_{1} = [ \begin{matrix}{x}_{1}^{2} & {y}_{1}^{2} & {z}_{1}^{2} & 2 {x}_{1} {y}_{1} & 2 {x}_{1} {z}_{1} & 2 {y}_{1} {z}_{1} \\ {x}_{2}^{2} & {y}_{2}^{2} & {z}_{2}^{2} & 2 {x}_{2} {y}_{2} & 2 {x}_{2} {z}_{2} & 2 {y}_{1} {z}_{2} \\ ⋮ & ⋮ & ⋮ & ⋮ & ⋮ & ⋮ \\ ⋮ & ⋮ & ⋮ & ⋮ & ⋮ & ⋮ \\ {x}_{N}^{2} & {y}_{N}^{2} & {z}_{N}^{2} & 2 {x}_{N} {y}_{N} & 2 {x}_{N} {z}_{N} & 2 {y}_{N} {z}_{N}\end{matrix} ] ;$$

$${D}_{2} = [ \begin{matrix}2 {x}_{1} & 2 {y}_{1} & 2 {z}_{1} & 1 \\ 2 {x}_{2} & 2 {y}_{2} & 2 {z}_{2} & 1 \\ ⋮ & ⋮ & ⋮ & ⋮ \\ ⋮ & ⋮ & ⋮ & ⋮ \\ 2 {x}_{N} & 2 {y}_{N} & 2 {z}_{N} & 1\end{matrix} ] ;$$

$${S}_{11} = {D}_{1}^{T} {D}_{1} , {S}_{12} = {D}_{1}^{T} {D}_{2} , {S}_{22} = {D}_{2}^{T} {D}_{2} .$$

$$C = [ \begin{matrix}{C}_{1} & {0}_{6 \times 4} \\ {0}_{4 \times 6} & {0}_{4 \times 4}\end{matrix} ] ;$$

$${C}_{1} = [ \begin{matrix}{C}_{11} & {0}_{3 \times 3} \\ {0}_{3 \times 3} & {C}_{22}\end{matrix} ] ;$$

$${C}_{11} = [ \begin{matrix}- 1 & k / 2 - 1 & k / 2 - 1 \\ k / 2 - 1 & - 1 & k / 2 - 1 \\ k / 2 - 1 & k / 2 - 1 & - 1\end{matrix} ] ;$$

$${C}_{22} = [ \begin{matrix}- k & 0 & 0 \\ 0 & - k & 0 \\ 0 & 0 & - k\end{matrix} ] .$$

Step 203-3: A parameter matrix related to the shape of the ellipsoid and a center point coordinate of the ellipsoid are determined according to the ellipsoid parameter.

According to Equation (9) and Equation (10), the center point coordinate X₀ of the ellipsoid and the parameter matrix A related to the shape of the ellipsoid can be determined.

$${X}_{0} = - {A}^{- 1} [ \begin{matrix}ξ ( 7 ) \\ ξ ( 8 ) \\ ξ ( 9 )\end{matrix} ] ; \qquad ( 9 )$$

$$A = [ \begin{matrix}ξ ( 1 ) & ξ ( 4 ) & ξ ( 5 ) \\ ξ ( 4 ) & ξ ( 2 ) & ξ ( 6 ) \\ ξ ( 5 ) & ξ ( 6 ) & ξ ( 3 )\end{matrix} ] ; \qquad ( 10 )$$

where ξ(1) is a first ellipsoid-related parameter; ξ(2) is a second ellipsoid-related parameter, and so on. ξ(10) is a tenth ellipsoid-related parameter.

Step 203-4: A new matrix is introduced, wherein the new matrix is a shape parameter matrix related to an ellipsoid semi-axis and a rotation angle.

Because the parameter matrix A can only determine that the measured data is fitted into a sphere by calibration, but it cannot determine whether the radius of the sphere is the standard magnetic field modulus, this embodiment improves the ellipsoid fitting method and introduces a new matrix Aₑ.

Step 203-5: an ellipsoid quadratic equation is transformed into a vector form according to the new matrix to obtain an ellipsoid vector equation.

Therefore, the ellipsoid quadratic Equation (i.e. Equation (6)) can be written in a vector form:

$${X}^{T} \text{?} X - 2 {X}_{0}^{T} \text{?} X + {X}_{0}^{T} {X}_{0} = 1 ; \qquad ( 11 )$$

$$where {X}_{0} = {A}^{- 1} [ \begin{matrix}ξ ( 7 ) \\ ξ ( 8 ) \\ ξ ( 9 )\end{matrix} ] = - {A}^{- 1} [ \begin{matrix}p \\ q \\ r\end{matrix} ]$$

$$\text{?} \text{indicates text missing or illegible when filed}$$

is the center point coordinate of the ellipsoid, and

$$\text{?} = [ \begin{matrix}a & d & e \\ d & b & f \\ e & f & c\end{matrix} ]$$

$$\text{?} \text{indicates text missing or illegible when filed}$$

is the shape parameter matrix related to the semi-axis of the ellipsoid and its rotation angle.

Step 203-6: The ellipsoid surface vector equation is compared with a quadratic standard equation to determine a positive definite matrix and the zero-bias error coefficient, wherein the quadratic standard equation is obtained by sorting out a modulus of the magnetic field intensity measured data and the error expression of the NV vector magnetometer.

Step 203-7: The positive definite matrix is decomposed to obtain the combination coefficient.

When the probe of the NV vector magnetometer makes various posture changes in a fixed geographical position, its magnetic field intensity is a constant in an ideal situation. Therefore, the modulus of the magnetic field intensity measured data is as follows:

$$‖ {B}_{c} ‖ = {( {B}_{c} )}^{T} \text{?} = {( \text{?} - {B}_{0} )}^{T} {( {K}^{- 1} )}^{T} {K}^{- 1} ( \text{?} - {B}_{0} ) \qquad ( 12 )$$

$$\text{?} \text{indicates text missing or illegible when filed}$$

After being sorted out, the measured vector of the NV vector magnetometer satisfies the quadratic standard equation:

$$( {B}_{c} \text{?} \frac{( {K}^{- 1} \text{?} ( {K}^{- 1} )}{‖ \text{?}} \text{?} \frac{{( {B}_{0} )}^{T} ( {K}^{- 1} \text{?} ( \text{?} ) {B}_{c}}{‖ \text{?}} \text{?} \frac{{( {B}_{0} )}^{T} ( {K}^{- 1} \text{?} ( \text{?} ) \text{?}}{‖ \text{?}} = 1 \qquad ( 13 )$$

$$\text{?} \text{indicates text missing or illegible when filed}$$

When the zero bias of the NV vector magnetometer is 0, for any magnetic field vector B_{c} that is not 0, the modulus of the magnetic field vector is always greater than zero, that is:

$${( {B}_{c} )}^{T} {( {K}^{- 1} )}^{T} ( {K}^{- 1} ) \text{?} = ‖ {B}_{c} \text{?} > 0 \qquad ( 14 )$$

$$\text{?} \text{indicates text missing or illegible when filed}$$

Therefore, the (K⁻¹)^{T}K⁻¹ matrix is a positive definite real matrix.

The ellipsoid surface vector equation (i.e. Equation (11)) is compared with the quadratic standard equation (i.e. Equation (13)), so that:

$$\text{?} = \frac{A}{{X}_{0}^{T} {AX}_{0} - ξ ( 10 )} ; \qquad ( 14 )$$

$$K {K}^{T} = \frac{\text{?}}{‖ \text{?}} = E \qquad ( 15 )$$

$${B}_{0} - {X}_{0}$$

$$\text{?} \text{indicates text missing or illegible when filed}$$

Therefore, X₀ is a zero-bias error coefficient,

$${X}_{0} = - {A}^{- 1} [ \begin{matrix}ξ ( 7 ) \\ ξ ( 8 ) \\ ξ ( 9 )\end{matrix} \text{?} A = [ \begin{matrix}ξ ( 1 ) & ξ ( 4 ) & ξ ( 5 ) \\ ξ ( 4 ) & ξ ( 2 ) & ξ ( 6 ) \\ ξ ( 5 ) & ξ ( 6 ) & ξ ( 3 )\end{matrix} ] ;$$

$$\text{?} \text{indicates text missing or illegible when filed}$$

E is a positive definite matrix, and Cholesky decomposition is performed on the E matrix to obtain the combination coefficient K of the measured magnetic field data and the actual magnetic field data.

Step 204: The determined error coefficient is substituted into the error expression of the NV vector magnetometer to obtain an error model of the NV vector magnetometer.

Step 205: The magnetic field intensity measured data is substituted into the error model of the NV vector magnetometer (i.e. Equation (4)) to obtain the corresponding magnetic field intensity real data.

In the actual process, the triaxial error factor of the non-orthogonal error coefficient and the triaxial error factor of the scale factor error coefficient can be calculated according to K in Equation (5) as needed in Step 206.

Step 206: A triaxial error factor of the non-orthogonal error coefficient and a triaxial error factor of the scale factor error coefficient are determined according to the combination coefficient.

The expressions of the triaxial error factor of the non-orthogonal error coefficient and the triaxial error factor of the scale factor error coefficient are:

$$\{ \begin{matrix}\text{?} = \frac{1}{K ( 1 )} \\ {k}_{y} = \frac{1}{K ( 5 )} \\ \text{?} = \frac{1}{K ( 9 )} \\ α = \frac{- K ( 3 )}{K ( 9 )} \\ β = \frac{- K ( 4 )}{K ( 1 )} \\ γ = \frac{- K ( 6 )}{K ( 9 )}\end{matrix} ; \qquad ( 16 )$$

$$\text{?} \text{indicates text missing or illegible when filed}$$

where kₓ, k_{y} and k_{z} are an x-axis error factor, a y-axis error factor and a z-axis error factor of the scale factor error coefficient, respectively; α, β and γ are three included angles of the non-orthogonal error coefficient, respectively; K is the combination coefficient, K is a matrix array with 3 rows and 3 columns, and the matrix array includes the triaxial error factor of the non-orthogonal error coefficient and the triaxial error factor of the scale factor error coefficient; K(1) is a numerical value corresponding to the first row and the first column in the matrix array; K(5) is a numerical value corresponding to the second row and the second column in the matrix array; K(9) is a numerical value corresponding to the third row and the third column in the matrix array; K(3) is a numerical value corresponding to the first row and the third column in the matrix array; K(4) is a numerical value corresponding to the second row and the first column in the matrix array; K(6) is a numerical value corresponding to the second row and the third column in the matrix array.

The above Step 201 to Step 206 are implemented. By rotating the probe of the NV vector magnetometer, the magnetic field data in different postures are collected and then fitted. The error calibration coefficient matrix (that is, error coefficient K) and nine parameters such as the zero bias, the scale factor and the non-orthogonal angle are obtained, thus completing the calibration of the diamond nitrogen-vacancy center (NV) magnetometer.

This embodiment discloses various error sources of the diamond nitrogen-vacancy center (NV) magnetometer, specifically involving the non-orthogonal error, the scale factor error and the zero-bias error. Based on these errors, the error model of the NV vector magnetometer is established, and the calculation equation of the error coefficient is derived. The improved ellipsoid fitting method is used, which effectively calibrates the error of the NV vector magnetometer, and solves the problems of low accuracy, low reliability and large errors in practical application.

Compared with the prior art, the error calibration method of the NV vector magnetometer according to the embodiment of the present disclosure not only can accurately calibrate the magnetometer itself, but also ensure that the stable and high-precision geomagnetic navigation detection services can still be provided in various environments, such as underground space, underwater and other scenes with complex electromagnetic interference. The calibration method is suitable for many different types of platforms. For both a manned underwater vehicle and an unmanned underwater vehicle, the accuracy and reliability of navigation and detection can be improved by the calibration method. The implementation of this embodiment will greatly promote the application of related technologies in military, geological exploration, marine development and other fields, and provide safer and more reliable navigation solutions for these industries.

In this embodiment, the diamond nitrogen vacancy (NV) magnetometer corrected based on the ellipsoidal fitting correction method is used, which has the following advantages. Compared with other types of magnetometers, a diamond nitrogen-vacancy center (NV) magnetometer is high in sensitivity, easy to be integrated and strong in working adaptability, which can meet the requirements of high precision in practical applications. Moreover, the diamond is high in temperature stability and small in shape change, so that the environment has little influence on the NV vector magnetometer. Because of the natural vector characteristics of the ensemble NV center, the NV vector magnetometer has greater advantages in orthogonality than other magnetometers. Compared with the application of the existing NV vector magnetometer, the NV vector magnetometer after error calibration is more suitable for high-precision navigation fields such as underwater and underground, which require strict orthogonality.

The present disclosure further provides an application scenario in which the above error calibration method of the NV vector magnetometer is applied. Specifically, the error calibration method of the NV vector magnetometer according to this embodiment can be applied to the magnetic abnormal data detection. The NV vector magnetometer collects magnetic field data. After preprocessing such as error calibration and denoising the collected magnetic field data, features are extracted from the preprocessed data. It is determined whether there are magnetic abnormal signals according to the extracted features. The error calibration method of the NV vector magnetometer according to this embodiment belongs to the preprocessing link of the magnetic field data in the magnetic abnormal data detection. By calibrating the error of the NV vector magnetometer, the accuracy and reliability of subsequent magnetic abnormal data detection can be ensured.

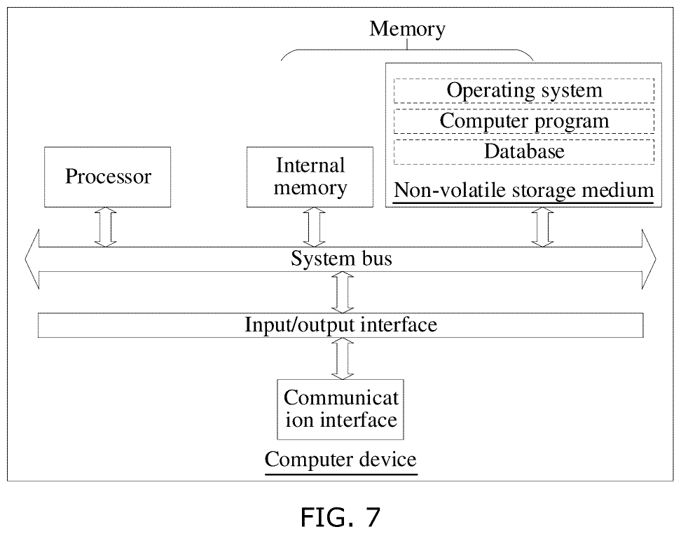

A second embodiment provides a computer device. The computer device may be a server or a terminal, the internal structure diagram of which may be as shown in FIG. 7. The computer device includes a processor, a memory, an input/output interface (I/O for short) and a communication interface. The processor, the memory and the input/output interface are connected through a system bus, and the communication interface is connected to the system bus through the input/output interface. The processor of the computer device is configured to provide computing and control capabilities. The memory of the computer device includes a non-volatile storage medium and an internal memory. The non-volatile storage medium stores an operating system, a computer program and a database. The internal memory provides an environment for the operation of the operating system and the computer program in the non-volatile storage medium. The database of the computer device is configured to store arrhythmia classification data using ECG signals. The input/output interface of the computer device is configured to exchange information between the processor and the external device. The communication interface of the computer device is configured to be communicated with an external terminal through network connection. The computer program, when executed by the processor, implements an error calibration method of an NV vector magnetometer in the first embodiment.

It can be understood by those skilled in the art that the structure shown in FIG. 7 is only a block diagram of a part of the structure related to the scheme of the present disclosure, and does not constitute a limitation on the computer device to which the scheme of the present disclosure is applied. The specific computer device may include more or less components than those shown in the figure, or combine some components, or have different component arrangements.

A third embodiment further provides a computer device, which includes a memory and a processor, wherein a computer program is stored in the memory, and the processor, when executing the computer program, implements the steps of the error calibration method of the NV vector magnetometer in the first embodiment.

A fourth embodiment further provides a computer-readable storage medium, on which a computer program is stored, wherein the computer program, when executed by a processor, implements the steps of the error calibration method of the NV vector magnetometer in the first embodiment.

A fifth embodiment further provides a computer program product, including a computer program, wherein the computer program, when executed by a processor, implements the steps of the error calibration method of the NV vector magnetometer in the first embodiment.

It should be noted that the user information (including but not limited to user equipment information, user personal information, etc.) and data (including but not limited to data for analysis, stored data, displayed data, etc.) involved in the present disclosure are all information and data authorized by users or fully authorized by all parties, and the collection, use and processing of relevant data should comply with relevant regulations.

Those skilled in the art can understand that all or part of the processes in the method of implementing the above embodiment can be completed by instructing related hardware through a computer program. The computer program can be stored in a non-volatile computer-readable storage medium, and when executed, the computer program can include the processes of the embodiments of the above method. Any reference to the memory, the database or other media used in various embodiments provided by the present disclosure may include at least one of a non-volatile memory and a volatile memory. The non-volatile memory may include a Read-Only Memory (ROM), a magnetic tape, a floppy disk, a flash memory, an optical memory, a high-density embedded non-volatile memory, a Resistive Random Access Memory (ReRAM), a Magneto-Resistive Random Access Memory (MRAM), a Ferroelectric Random Access Memory (FRAM), a Phase Change Memory (PCM), a graphene memory, etc. The volatile memory may include a Random Access Memory (RAM) or an external cache memory. By way of illustration and not limitation, RAM can be in various forms, such as a Static Random Access Memory (SRAM) or a Dynamic Random Access Memory (DRAM).

The databases involved in various embodiments provided by the present disclosure may include at least one of a relational database and a non-relational database. The non-relational database may include, but is not limited to, a distributed database based on a blockchain. The processors involved in the embodiments according to the present disclosure can be, but are not limited to, general processors, central processing units, graphics processors, digital signal processors, programmable logics, data processing logics based on quantum computing, etc.

The technical features of the above embodiments can be combined at will. In order to make the description concise, not all possible combinations of the technical features in the above embodiments are described. However, as long as there is no contradiction between the combinations of these technical features, the combinations should be considered as the scope recorded in this specification.

In the present disclosure, specific examples are applied to illustrate the principle and implementation of the present disclosure, and the explanations of the above embodiments are only used to help understand the method and core ideas of the present disclosure. At the same time, according to the idea of the present disclosure, there will be some changes in the detailed description and application scope for those skilled in the art. To sum up, the contents of the specification should not be construed as limiting the present disclosure.

What is claimed is:

1. An error calibration method of a nitrogen-vacancy center (NV) vector magnetometer, wherein the error calibration method comprises:
acquiring corresponding magnetic field intensity NV vector magnetometer measured data in various postures;
constructing an error expression of the NV vector magnetometer, wherein the error expression of the NV vector magnetometer is a relational expression among the magnetic field intensity measured data, magnetic field intensity real data and an error coefficient, and wherein the error coefficient comprises a combination coefficient and a zero-bias error coefficient, the combination coefficient comprising a non-orthogonal error coefficient and a scale factor error coefficient;
fitting all the magnetic field intensity measured data based on an ellipsoid fitting method of a least square method;
solving the error coefficient to obtain a determined error coefficient;
substituting the determined error coefficient into the error expression of the NV vector magnetometer to obtain an error model of the NV vector magnetometer; and
substituting the magnetic field intensity measured data into the error model of the NV vector magnetometer to obtain the corresponding magnetic field intensity real data.

2. The error calibration method according to claim 1, wherein the magnetic field intensity measured data obtained by the NV vector magnetometer in each posture is data in a set space range, and wherein the set space range is a three-dimensional space range where the ellipsoid to be fitted is located.

3. The error calibration method according to claim 1, wherein the error expression of the NV vector magnetometer is:
$${B}_{c} = {( {K}_{non} {K}_{sca} )}^{- 1} ▯ ( \text{?} - {B}_{0} ) = {K}^{- 1} ▯ ( {B}_{s} - {B}_{0} )$$
$$\text{?} \text{indicates text missing or illegible when filed}$$
where B_{c} is the magnetic field intensity measured data; Kₙₒₙ is the non-orthogonal error coefficient; K_{sca} is the scale factor error coefficient; Bₛ is the corresponding magnetic field intensity real data; B₀ is the zero-bias error coefficient; and K is the combination coefficient.

4. The error calibration method according to claim 1, wherein fitting all the magnetic field intensity measured data and solving the error coefficient to obtain the determined error coefficient comprises:
establishing an objective function based on an ellipsoid parameter and a first distance;
taking the minimum sum of squares of all the first distances as an objective, wherein the first distance is a distance from a magnetic field intensity measured data point to an ellipsoid surface, and the magnetic field intensity measured data point is a three-dimensional coordinate point of the magnetic field intensity measured data;
solving the objective function by using a least square method to determine the ellipsoid parameter;
determining a parameter matrix related to the shape of the ellipsoid and a center point coordinate of the ellipsoid according to the ellipsoid parameter;
introducing a new matrix, wherein the new matrix is a shape parameter matrix related to an ellipsoid semi-axis and a rotation angle;
transforming an ellipsoid quadratic equation into a vector form according to the new matrix to obtain an ellipsoid vector equation;
comparing the ellipsoid vector equation with a quadratic standard equation to determine a positive definite matrix and the zero-bias error coefficient, wherein the quadratic standard equation is obtained by sorting out a modulus of the magnetic field intensity measured data and the error expression of the NV vector magnetometer; and
decomposing the positive definite matrix to obtain the combination coefficient.

5. The error calibration method according to claim 4, wherein the expression of the new matrix is:
$$\text{?} = \frac{A}{{X}_{0}^{T} {AX}_{0} - ξ ( 10} ;$$
$$\text{?} \text{indicates text missing or illegible when filed}$$
where Aₑ is the new matrix; A is the parameter matrix; X₀ is the center point coordinate; ξ is the ellipsoid parameter, the ellipsoid parameter being a one-dimensional array that comprises a preset number of ellipsoid-related parameters; and ξ(10) is a tenth ellipsoid-related parameter.

6. The error calibration method according to claim 4, wherein after substituting the magnetic field intensity measured data into the error model of the NV vector magnetometer to obtain the corresponding magnetic field intensity real data, the error calibration method further comprises determining a triaxial error factor of the non-orthogonal error coefficient and a triaxial error factor of the scale factor error coefficient according to the combination coefficient.

7. The error calibration method according to claim 6, wherein the expressions of the triaxial error factor of the non-orthogonal error coefficient and the triaxial error factor of the scale factor error coefficient are:
$$\{ \begin{matrix}\text{?} = \frac{1}{K ( 1 )} \\ {k}_{y} = \frac{1}{K ( 5 )} \\ {k}_{z} = \frac{1}{K ( 9 )} \\ α = \frac{- K ( 3 )}{K ( 9 )} \\ β = \frac{- K ( 4 )}{K ( 1 )} \\ γ = \frac{- K ( 6 )}{K ( 9 )}\end{matrix}$$
$$\text{?} \text{indicates text missing or illegible when filed}$$
where kₓ, k_{y} and k_{z} are an x-axis error factor, a y-axis error factor and a z-axis error factor of the scale factor error coefficient, respectively; α, β and γ are three included angles of the non-orthogonal error coefficient, respectively; K is the combination coefficient, K is a matrix array with 3 rows and 3 columns, and the matrix array comprises the triaxial error factor of the non-orthogonal error coefficient and the triaxial error factor of the scale factor error coefficient; K(1) is a numerical value corresponding to the first row and the first column in the matrix array; K(5) is a numerical value corresponding to the second row and the second column in the matrix array; K(9) is a numerical value corresponding to the third row and the third column in the matrix array; K(3) is a numerical value corresponding to the first row and the third column in the matrix array; K(4) is a numerical value corresponding to the second row and the first column in the matrix array; and K(6) is a numerical value corresponding to the second row and the third column in the matrix array.

8. A computer device, comprising:
a processor;
a memory storing a computer program that, when executed by the processor, causes the processor to implement an error calibration method of a nitrogen-vacancy center (NV) vector magnetometer comprising:
acquiring corresponding magnetic field intensity NV vector magnetometer measured data in various postures;
constructing an error expression of the NV vector magnetometer, wherein the error expression of the NV vector magnetometer is a relational expression among the magnetic field intensity measured data, magnetic field intensity real data and an error coefficient, and wherein the error coefficient comprises a combination coefficient and a zero-bias error coefficient, the combination coefficient comprising a non-orthogonal error coefficient and a scale factor error coefficient;
fitting all the magnetic field intensity measured data based on an ellipsoid fitting method of a least square method;
solving the error coefficient to obtain a determined error coefficient;
substituting the determined error coefficient into the error expression of the NV vector magnetometer to obtain an error model of the NV vector magnetometer; and
substituting the magnetic field intensity measured data into the error model of the NV vector magnetometer to obtain the corresponding magnetic field intensity real data.

9. The computer device according to claim 8, wherein the magnetic field intensity measured data obtained by the NV vector magnetometer in each posture is data in a set space range, and wherein the set space range is a three-dimensional space range where the ellipsoid to be fitted is located.

10. The computer device according to claim 8, wherein the error expression of the NV vector magnetometer is:
$${B}_{c} = {( {K}_{non} {K}_{sca} )}^{- 1} ▯ ( {B}_{s} - {B}_{0} ) = {K}^{- 1} ▯ ( {B}_{s} - {B}_{0} )$$
where B_{c} is the magnetic field intensity measured data; Kₙₒₙ is the non-orthogonal error coefficient; K_{sca} is the scale factor error coefficient; Bₛ is the corresponding magnetic field intensity real data; B₀ is the zero-bias error coefficient; and K is the combination coefficient.

11. The computer device according to claim 8, wherein fitting all the magnetic field intensity measured data and solving the error coefficient to obtain the determined error coefficient, comprises:
establishing an objective function based on an ellipsoid parameter and a first distance;
taking the minimum sum of squares of all the first distances as an objective, wherein the first distance is a distance from a magnetic field intensity measured data point to an ellipsoid surface, and the magnetic field intensity measured data point is a three-dimensional coordinate point of the magnetic field intensity measured data;
solving the objective function by using a least square method to determine the ellipsoid parameter;
determining a parameter matrix related to the shape of the ellipsoid and a center point coordinate of the ellipsoid according to the ellipsoid parameter;
introducing a new matrix, wherein the new matrix is a shape parameter matrix related to an ellipsoid semi-axis and a rotation angle;
transforming an ellipsoid quadratic equation into a vector form according to the new matrix to obtain an ellipsoid vector equation;
comparing the ellipsoid vector equation with a quadratic standard equation to determine a positive definite matrix and the zero-bias error coefficient, wherein the quadratic standard equation is obtained by sorting out a modulus of the magnetic field intensity measured data and the error expression of the NV vector magnetometer; and
decomposing the positive definite matrix to obtain the combination coefficient.

12. The computer device according to claim 11, wherein the expression of the new matrix is:
$${A}_{e} = \frac{A}{\text{?} {AX}_{0} - ξ ( 10 )} ;$$
$$\text{?} \text{indicates text missing or illegible when filed}$$
where Aₑ is the new matrix; A is the parameter matrix; X₀ is the center point coordinate; ξ is the ellipsoid parameter, the ellipsoid parameter being a one-dimensional array that comprises a preset number of ellipsoid-related parameters; and ξ(10) is a tenth ellipsoid-related parameter.

13. The computer device according to claim 11, wherein after substituting the magnetic field intensity measured data into the error model of the NV vector magnetometer to obtain the corresponding magnetic field intensity real data”, the error calibration method further comprises determining a triaxial error factor of the non-orthogonal error coefficient and a triaxial error factor of the scale factor error coefficient according to the combination coefficient.

14. The computer device according to claim 13, wherein the expressions of the triaxial error factor of the non-orthogonal error coefficient and the triaxial error factor of the scale factor error coefficient are:
$$\{ \begin{matrix}{k}_{x} = \frac{1}{K ( 1 )} \\ {k}_{y} = \frac{1}{K ( 5 )} \\ {k}_{z} = \frac{1}{K ( 9 )} \\ α = \frac{- K ( 3 )}{K ( 9 )} \\ β = \frac{- K ( 4 )}{K ( 1 )} \\ γ = \frac{- K ( 6 )}{K ( 9 )}\end{matrix}$$
where kₓ, k_{y} and k_{z} are an x-axis error factor, a y-axis error factor and a z-axis error factor of the scale factor error coefficient, respectively; α, β and γ are three included angles of the non-orthogonal error coefficient, respectively; K is the combination coefficient, K is a matrix array with 3 rows and 3 columns, and the matrix array comprises the triaxial error factor of the non-orthogonal error coefficient and the triaxial error factor of the scale factor error coefficient; K(1) is a numerical value corresponding to the first row and the first column in the matrix array; K(5) is a numerical value corresponding to the second row and the second column in the matrix array; K(9) is a numerical value corresponding to the third row and the third column in the matrix array; K(3) is a numerical value corresponding to the first row and the third column in the matrix array; K(4) is a numerical value corresponding to the second row and the first column in the matrix array; and K(6) is a numerical value corresponding to the second row and the third column in the matrix array.

15. A non-transitory computer-readable storage medium on which a computer program is stored, wherein the computer program, when executed by a processor, implements an error calibration method of a nitrogen-vacancy center (NV) vector magnetometer comprising:
acquiring corresponding magnetic field intensity NV vector magnetometer measured data in various postures;
constructing an error expression of the NV vector magnetometer, wherein the error expression of the NV vector magnetometer is a relational expression among the magnetic field intensity measured data, magnetic field intensity real data and an error coefficient, and wherein the error coefficient comprises a combination coefficient and a zero-bias error coefficient, the combination coefficient comprising a non-orthogonal error coefficient and a scale factor error coefficient;
fitting all the magnetic field intensity measured data based on an ellipsoid fitting method of a least square method;
solving the error coefficient to obtain a determined error coefficient;
substituting the determined error coefficient into the error expression of the NV vector magnetometer to obtain an error model of the NV vector magnetometer; and
substituting the magnetic field intensity measured data into the error model of the NV vector magnetometer to obtain the corresponding magnetic field intensity real data.

16. The non-transitory computer-readable storage medium according to claim 15, wherein the magnetic field intensity measured data obtained by the NV vector magnetometer in each posture is data in a set space range, and wherein the set space range is a three-dimensional space range where the ellipsoid to be fitted is located.

17. The non-transitory computer-readable storage medium according to claim 15, wherein the error expression of the NV vector magnetometer is:
$${B}_{c} = {( {K}_{non} {K}_{sca} )}^{- 1} ▯ ( {B}_{s} - {B}_{0} ) = {K}^{- 1} ▯ ( {B}_{s} - {B}_{0} )$$
where B_{c} is the magnetic field intensity measured data; Kₙₒₙ is the non-orthogonal error coefficient; K_{sca} is the scale factor error coefficient; Bₛ is the corresponding magnetic field intensity real data; B₀ is the zero-bias error coefficient; and K is the combination coefficient.

18. The non-transitory computer-readable storage medium according to claim 15, wherein fitting all the magnetic field intensity measured data based on an ellipsoid fitting method of a least square method, and solving the error coefficient to obtain the determined error coefficient, comprises:
establishing an objective function based on an ellipsoid parameter and a first distance;
taking the minimum sum of squares of all the first distances as an objective, wherein the first distance is a distance from a magnetic field intensity measured data point to an ellipsoid surface, and the magnetic field intensity measured data point is a three-dimensional coordinate point of the magnetic field intensity measured data;
solving the objective function by using a least square method to determine the ellipsoid parameter;
determining a parameter matrix related to the shape of the ellipsoid and a center point coordinate of the ellipsoid according to the ellipsoid parameter;
introducing a new matrix, wherein the new matrix is a shape parameter matrix related to an ellipsoid semi-axis and a rotation angle;
transforming an ellipsoid quadratic equation into a vector form according to the new matrix to obtain an ellipsoid vector equation;
comparing the ellipsoid vector equation with a quadratic standard equation to determine a positive definite matrix and the zero-bias error coefficient, wherein the quadratic standard equation is obtained by sorting out a modulus of the magnetic field intensity measured data and the error expression of the NV vector magnetometer; and
decomposing the positive definite matrix to obtain the combination coefficient.

19. The non-transitory computer-readable storage medium according to claim 18, wherein the expression of the new matrix is:
$$\text{?} = \frac{A}{{X}_{0}^{T} {AX}_{0} - ξ ( 10 )} ;$$
$$\text{?} \text{indicates text missing or illegible when filed}$$
where Aₑ is the new matrix; A is the parameter matrix; X₀ is the center point coordinate; ξ is the ellipsoid parameter, the ellipsoid parameter being a one-dimensional array that comprises a preset number of ellipsoid-related parameters; and ξ(10) is a tenth ellipsoid-related parameter.

20. The non-transitory computer-readable storage medium according to claim 18, wherein after substituting the magnetic field intensity measured data into the error model of the NV vector magnetometer to obtain the corresponding magnetic field intensity real data”, the error calibration method further comprises determining a triaxial error factor of the non-orthogonal error coefficient and a triaxial error factor of the scale factor error coefficient according to the combination coefficient.
